(19) United States
(12) Patent Application Publication
(10) Pub. No.: US 2009/0117711 A1
(43) Pub. Date: May 7, 2009

(54) Method for Laterally Cutting Through a Semiconductor Wafer and Optoelectronic Component

(75) Inventors: Volker Harle, Laaber (DE); Christoph Eichler, Tegernheim (DE)

Correspondence Address: COHEN, PONTANI, LIEBERMAN & PAVANE LLP, 551 FIFTH AVENUE, SUITE 1210, NEW YORK, NY, 10176, US

(73) Assignee: Osram Opto Semiconductors GmbH, Regensburg (DE)

(21) Appl. No.: 11/991,489

(22) PCT Filed: Aug. 4, 2006
(86) PCT No.: PCT/DE2006/001366

§ 371 Date: Dec. 30, 2008

(30) Foreign Application Priority Data
Sep. 1, 2005 (DE) 10 2005 041 571.7
Nov. 2, 2005 (DE) 10 2005 052 358.7

(51) Int. Cl. H01L 21/02

(52) U.S. Cl. 438/463; 257/E21.002

(57) ABSTRACT

In a method for laterally dividing a semiconductor wafer (1), a growth substrate (2) is provided, onto which is grown a semiconductor layer sequence (3) comprising a layer provided as a separating layer (4) and at least one functional semiconductor layer (5) which succeeds the separating layer (4) in the growth direction. Afterward, ions are implanted into the separating layer (4) through the functional semiconductor layer (5), and the semiconductor wafer is divided along the separating layer (4), a part (1a) of the semiconductor wafer (1) which contains the growth substrate (2) being separated.

This patent application claims the priority of German patent applications 10 2005 052 358.7 and 10 2005 041 571.7, the disclosure content of which is hereby incorporated by reference.

The invention relates to a method for laterally dividing a semiconductor wafer, in particular an optoelectronic semiconductor wafer, in which a growth substrate is separated from the semiconductor wafer, and an optoelectronic component.

In the production of optoelectronic components, for example LEDs or semiconductor lasers, it is often desirable for a growth substrate used for the epitaxial growth of a semiconductor layer sequence of the optoelectronic component to be subsequently separated from the semiconductor wafer.

By way of example, in so-called thin-film technology, firstly the semiconductor layer sequence of an optoelectronic component is grown epitaxially on a growth substrate, afterward a carrier is applied to the surface of the semiconductor layer sequence opposite to the growth substrate, and the growth substrate is subsequently separated. This method has the advantage, on the one hand, that a comparatively thin epitaxial layer sequence remains on the new carrier, from which layer sequence the radiation emitted by the optoelectronic component can be coupled out with high efficiency, particularly if a reflective or reflection-increasing layer is provided between the epitaxial layer sequence and the new carrier. Furthermore, the growth substrate can advantageously be reused after it has been stripped away. This is advantageous particularly when the growth substrate is composed of a comparatively high-priced material, in particular sapphire, SiC, GaN or AlN.

A method for laterally dividing a semiconductor wafer is described for example in the document U.S. Pat. No. 5,374,564.

Furthermore, U.S. Pat. No. 6,815,309 discloses a method for laterally dividing a semiconductor wafer in which a thin layer of an epitaxial substrate is transferred to another, lower-priced substrate in order in this way to produce a quasi-substrate suitable for the epitaxy. In this case, the epitaxial substrate is gradually consumed by repeated stripping away of thin layers that are in each case applied to new carrier substrates. In a method of this type there is the risk of the thin layer of the epitaxial substrate which is applied to the new carrier substrate possibly being damaged by the previously effected ion implantation, which is effected through the substrate layer to be stripped away. This could possibly have an adverse effect on the crystal quality of the epitaxial layers when growing epitaxial layers onto the quasi-substrate.

The document C. H. Yun, N. W. Cheung: Thermal and Mechanical Separation of Silicon Layers from Hydrogen Pattern-Implanted Wafers, Journ. of Electronic Materials, vol. 30, No. 8, 2001, pp. 960-964 discloses a method for thermally or mechanically separating a silicon layer from a silicon wafer.

The invention is based on the object of specifying an improved method for separating a growth substrate from a semiconductor wafer, and an optoelectronic component comprising a semiconductor layer sequence grown on a growth substrate, in which the risk of damage to the growth substrate by an ion implantation effected prior to the epitaxial growth of semiconductor layers is reduced. Furthermore, the growth substrate is preferably intended to be stripped away from the semiconductor wafer without any residues and therefore to be completely reusable.

This object is achieved by means of a method having the features of patent claim 1 and an optoelectronic component in accordance with patent claim 23. The dependant claims relate to advantageous configurations and developments of the invention.

In a method for laterally dividing a semiconductor wafer according to the invention, a growth substrate is provided, onto which a semiconductor layer sequence is grown epitaxially, the semiconductor layer sequence comprising a layer provided as a separating layer and at least one functional semiconductor layer which succeeds the separating layer in the growth direction. Afterward, ions are implanted into the separating layer through the functional semiconductor layer and the semiconductor wafer is divided, a part of the semiconductor wafer which contains the growth substrate being separated along the separating layer.

By virtue of the fact that the ion implantation is not effected into the growth substrate but rather into a separating layer contained in the epitaxially grown semiconductor layer sequence, a part of the semiconductor wafer which contains the entire growth substrate is separated when dividing the semiconductor wafer along the separating layer. The semiconductor wafer is divided in a lateral direction running in a plane of the separating layer. Therefore, when dividing the semiconductor wafer, the growth substrate is advantageously not severed and can be completely reused. In particular, a layer sequence can repeatedly be grown on the growth substrate and be subsequently separated without the growth substrate being progressively consumed in the process. This is advantageous in particular when a high-priced substrate is used as a growth substrate, such as, for example, a GaN substrate, an AlN substrate, a sapphire substrate or an SiC substrate.

Dividing is preferably effected by means of a thermal treatment, preferably at a temperature within the range of 300° C. to 1200° C. In particular, the thermal treatment can be effected at a temperature of between 300° C. and 900° C. In this case, the implanted ions diffuse in the separating layer and produce blisters. The propagation of the blisters in the separating layer finally leads to the semiconductor wafer being divided into a first part, which contains the growth substrate, and a second part which contains the functional semiconductor layer. A part of the semiconductor wafer which contains the growth substrate is separated in this way.

During the thermal treatment, the heating of the separating layer can be brought about both by increasing the ambient temperature and by local heating by means of electromagnetic radiation, for example laser or microwave radiation.

As an alternative, the semiconductor wafer can also be separated mechanically along the implantation regions, for example by connecting the opposite surfaces of the semiconductor wafer to auxiliary carriers and exerting a torque on them, such that the semiconductor wafer is divided along the separating layer.

After the method step of dividing the semiconductor wafer for separating the growth substrate, the growth substrate can contain a separated part of the separating layer. This part of the separating layer which is contained on the growth substrate after separation is preferably subsequently removed from the growth substrate, for example by means of an etching or polishing process, in order to prepare the growth substrate for the epitaxial growth of further semiconductor layer sequences.

The semiconductor layer sequence is preferably based on a nitride compound semiconductor material. Hereinafter, “based on a nitride compound semiconductor material” means that a component or part of a component designated in this way preferably comprises InₓAl_{y}Ga_{1-x-y}N, where 0≦x≦1, 0≦y≦1 and x+y≦1 hold true. In this case, said material need not necessarily have a mathematically exact composition according to the above formula. Rather, it can have one or more dopants and additional constituents which essentially do not change the physical properties of the material. For the sake of simplicity, however, the above formula only comprises the essential constituents of the crystal lattice (Al, Ga, In, N) even if these can be replaced in part by small quantities of further substances.

Preferably, hydrogen ions are implanted into the separating layer through the functional semiconductor layer. As an alternative, it is also possible to use ions of noble gases such as, for example, helium, neon, krypton or xenon.

It is also possible for ions of different atoms to be implanted, in particular hydrogen ions and helium ions or hydrogen ions and boron ions. This has the advantage that the required implantation dose is reduced.

The thermal treatment carried out for separating a part of the semiconductor wafer which contains the growth substrate is preferably effected at a temperature within the range of 300° C. to 900° C. In this case, the implanted ions diffuse in the separating layer and produce blisters.

After the ion implantation, thermal annealing of the semiconductor layer sequence is preferably effected in order to reduce a possible impairment of the layer quality which might occur on account of the ion implantation effected through the semiconductor layer sequence. The thermal annealing does not have to be effected directly after the ion implantation, but rather can in particular also be effected only after the semiconductor wafer has been divided, if for example the blister formation that leads to the dividing of the semiconductor wafer already commences at a temperature lower than the temperature required for the annealing process.

The separating layer preferably contains at least one element which has a higher atomic number than gallium, for example indium. The element having the higher atomic number than gallium can be introduced into the separating layer as a dopant or preferably be a constituent of the semiconductor material of the separating layer. In particular, the separating layer can be an InGaN layer. The presence of an element having a high atomic number in the separating layer has the advantage that the ions penetrating into the separating layer during the ion implantation are decelerated and, consequently, further penetration is reduced. In this case, therefore, the separating layer acts as a stop layer for the implanted ions.

This is advantageous particularly when comparatively high-energy ions are implanted during the ion implantation, in order to reduce possible damage to the functional semiconductor layer. In particular, it has been found that damage to the functional semiconductor layer can be reduced by increasing the ion energy during the ion implantation. However, increasing the ion energy generally has the consequence that the implanted ions form a wider and flatter concentration profile in a direction perpendicular to the plane of the separating layer, which might adversely affect the stripping process. The full width at half maximum of the concentration profile of the implanted ions may be for example approximately 200 nm.

By virtue of the fact that the separating layer contains at least one element having an atomic number greater than that of gallium, it is possible to obtain a comparatively narrow concentration profile in the separating layer even when the implanted ions have a comparatively high ion energy, whereby the separating method step is facilitated.

In a further advantageous configuration of the invention, the semiconductor layer sequence contains at least one diffusion barrier layer—adjacent to the separating layer—for the implanted ions. In this case, a diffusion barrier layer is understood to be a layer in which the implanted ions have a lower diffusion coefficient than in the separating layer. The diffusion barrier layer can be arranged above and/or below the separating layer in the growth direction of the semiconductor layer sequence.

The diffusion barrier layer advantageously contains a nitride compound semiconductor material doped with Zn, Fe or Si, and is preferably not p-doped. In particular, it has been found that hydrogen has a lower diffusion coefficient in comparatively high-impedance Zn-doped GaN or Si-doped n-GaN than in Mg-doped p-GaN.

Diffusion of the implanted ions into the functional semiconductor layer can be reduced in particular by means of a diffusion barrier layer that is arranged above the separating layer as seen in the growth direction of the layer sequence. Otherwise, diffusion of the implanted ions could impair the quality of the functional semiconductor layer.

Particularly preferably, a diffusion barrier layer is arranged on both sides of the separating layer, that is to say both above and below the separating layer in the growth direction of the semiconductor layer sequence. Diffusion of the implanted ions in a direction running perpendicular to the plane of the separating layer is reduced by the diffusion barrier layer or the diffusion barrier layers. An undesirable widening of the concentration profile of the implanted ions in a direction perpendicular to the layer plane of the separating layer is counteracted in this way.

In a further preferred embodiment of the invention, the separating layer is a tensile-stressed layer. In this case, the lattice constant of the separating layer is lower than the lattice constant of at least one layer adjoining the separating layer. A consequence of this is that the separating layer is subjected to a tensile stress. Preferably, the tensile-stressed layer is a nitride compound semiconductor layer containing aluminum. In this case, the tensile stress of the separating layer can be brought about for example by the separating layer being adjoined by a further nitride compound semiconductor layer, which has a lower proportion of aluminum than the separating layer or even free of aluminum. In particular, an InGaN layer can adjoin the separating layer. A tensile stress of the separating layer can furthermore be produced by doping the separating layer with silicon. The tensile stress of the separating layer advantageously facilitates the separating method step since the interface between the tensile-stressed separating layer and the adjoining layer having a higher lattice constant in this case acts as a desired breaking location.

Furthermore, in the case of the invention, the separating method step can advantageously be facilitated by the separating layer being a semiconductor layer produced by lateral epitaxial overgrowth (ELOG). In this case, the separating layer is not grown directly on the growth substrate or onto a semiconductor layer already applied to the growth substrate, rather a mask layer is applied beforehand to the growth substrate or the semiconductor layer on which the separating layer is intended to be grown. The mask layer is preferably a silicon nitride layer or a silicon dioxide layer. The epitaxial growth of the separating layer commences in the regions of the growth substrate or of the semiconductor layer provided for the growth which are not covered by the mask layer, the masked regions subsequently being overgrown in the lateral direction. Since the adhesion of a separating layer produced by lateral epitaxial overgrowth on the laterally overgrown mask layer is only low, the interfaces between the mask layer and the separating layer act as desired breaking locations in the separating method step.

Furthermore, it is advantageous if the separating layer is formed from a semiconductor material in which the implanted ions have a greater diffusion coefficient than in a layer adjoining the separating layer. This increases the diffusion of the implanted ions within the separating layer, that is to say in particular in a direction running parallel to the plane of the semiconductor wafer, and therefore provides the formation of blisters in the separating layer, whereby the separating method step is facilitated. The diffusion-promoting separating layer is preferably a p-doped nitride compound semiconductor layer, which can be doped with Mg, for example. In particular, it has been found that hydrogen has a higher diffusion coefficient in p-doped GaN than in a Zn-doped high-impedance GaN layer or a silicon-doped n-GaN layer.

The semiconductor wafer is preferably connected to a carrier substrate prior to dividing the part which contains the growth substrate at a surface remote from the growth substrate. The carrier substrate simplifies the handling of the epitaxial layer sequence separated from the growth substrate and can function in particular as a carrier for an optoelectronic component produced from the semiconductor layer sequence.

The carrier substrate can be an intermediate carrier, provision being made for separating or detaching the intermediate carrier in a subsequent method step. By way of example, the intermediate carrier is a glass substrate. The glass substrate is preferably connected to the semiconductor layer sequence by means of an interlayer composed of a silicon oxide. In this case, in a later method step, the intermediate carrier including the interlayer can be dissolved for example in hydrofluoric acid (HF).

The functional semiconductor layer is preferably a radiation-emitting or radiation-detecting layer. In particular, the functional semiconductor layer can be the active layer of a luminance diode or of a semiconductor laser. The functional semiconductor layer particularly preferably has InₓAl_{y}Ga_{1-x-y}N where 0≦x≦1, 0≦y≦1 and x+y≦1.

As an alternative, the semiconductor layer sequence can also be based on a phosphide compound semiconductor or an arsenide compound semiconductor. In this case, the semiconductor layer sequence, and in particular the functional semiconductor layer, preferably has InₓAl_{y}Ga_{1-x-y}P or InₓAl_{y}Ga_{1-x-y}As where 0≦x≦1, 0≦y≦1 and x+y<1.

In a further preferred embodiment of the invention, the semiconductor layer sequence contains one or more further separating layers which succeed the separating layer in the growth direction. A functional semiconductor layer preferably succeeds each separating layer in the growth direction. A semiconductor layer sequence composed of a plurality of partial layer sequences is therefore applied to the growth substrate, the partial layer sequences in each case being separated from one another by a separating layer.

In this case, firstly an ion implantation is effected into an upper separating layer which is at the largest distance from the growth substrate. Preferably, the semiconductor layer sequence is subsequently connected to a carrier substrate at a side remote from the growth substrate. Afterward, the semiconductor wafer is divided along the upper separating layer, for example by means of a thermal treatment. In this way, the partial layer sequence arranged above the upper separating layer is separated from the semiconductor wafer and transferred to the carrier substrate. The abovementioned method steps are carried out repeatedly in accordance with the number of separating layers in order to separate the plurality of partial layer sequences from the semiconductor wafer progressively by dividing the semiconductor wafer along the respective separating layer.

A growth substrate can thus advantageously be used for growing a plurality of partial layer sequences with functional semiconductor layers which are successively separated from the semiconductor wafer by means of ion implantation and a subsequent separating process and are in each case transferred to a carrier substrate.

An optoelectronic component according to the invention contains a semiconductor layer sequence having a functional semiconductor layer, wherein the semiconductor layer sequence was separated from a growth substrate by the above-described method for laterally dividing a semiconductor wafer. In particular, the optoelectronic component can be a luminescence diode or a semiconductor laser.

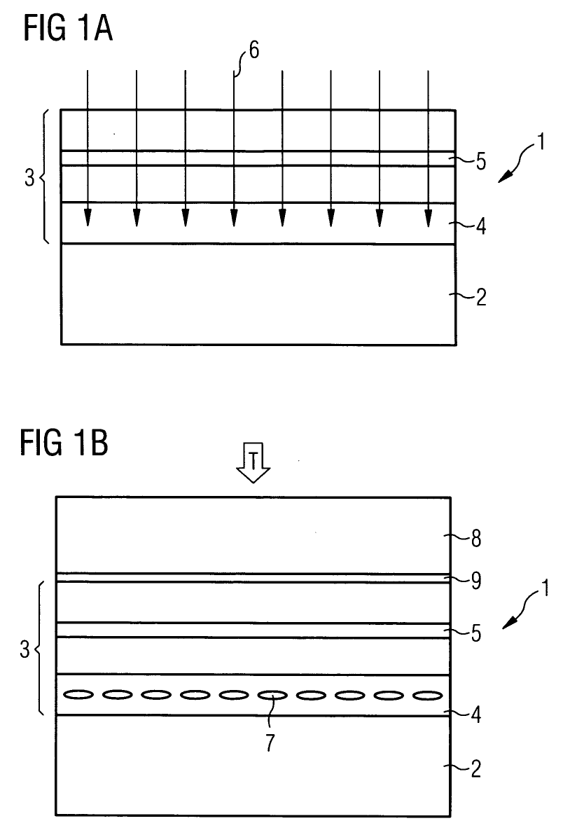

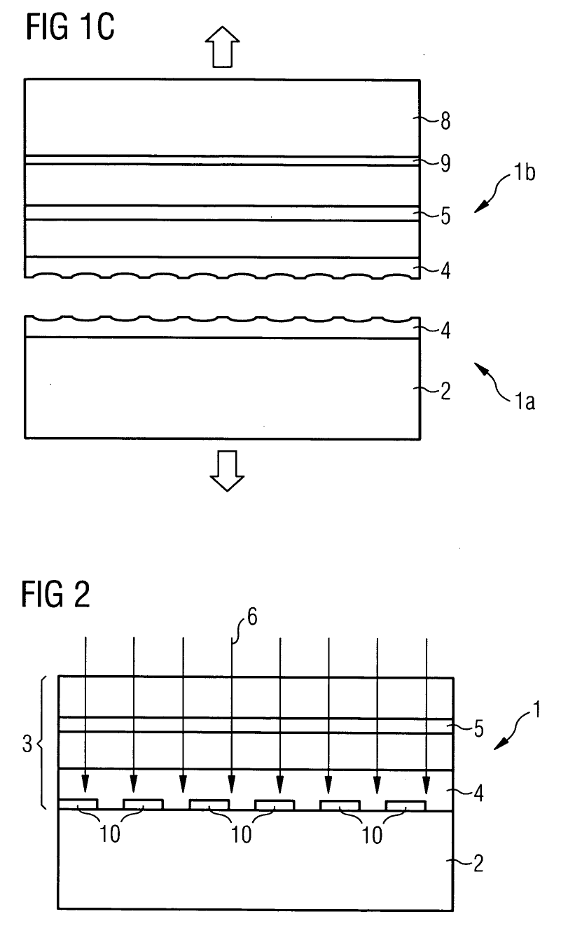

The invention is explained in more detail below on the basis of exemplary embodiments in connection with FIGS. 1 to 6. In the figures:

FIGS. 1A, 1B and 1C show schematic illustrations of a cross section through a semiconductor wafer during intermediate steps of a method in accordance with a first exemplary embodiment of the invention,

FIG. 2 shows a schematic illustration of a cross section through a semiconductor wafer during an intermediate step of a method in accordance with a second exemplary embodiment of the invention,

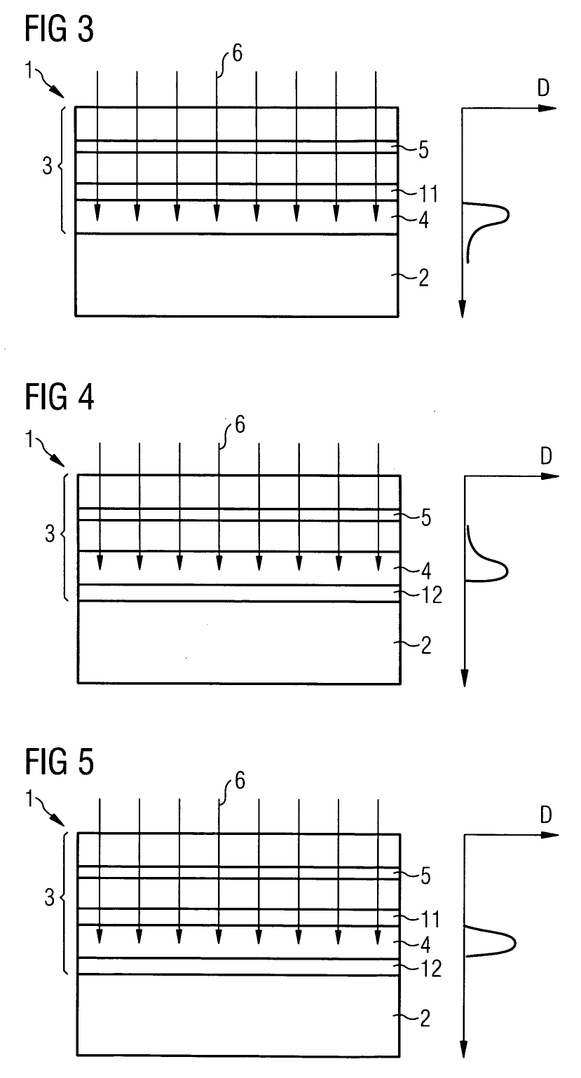

FIG. 3 shows a schematic illustration of a cross section through a semiconductor wafer during an intermediate step of a method in accordance with a third exemplary embodiment of the invention,

FIG. 4 shows a schematic illustration of a cross section through a semiconductor wafer during an intermediate step of a method in accordance with a fourth exemplary embodiment of the invention,

FIG. 5 shows a schematic illustration of a cross section through a semiconductor wafer during an intermediate step of a method in accordance with a fifth exemplary embodiment of the invention, and

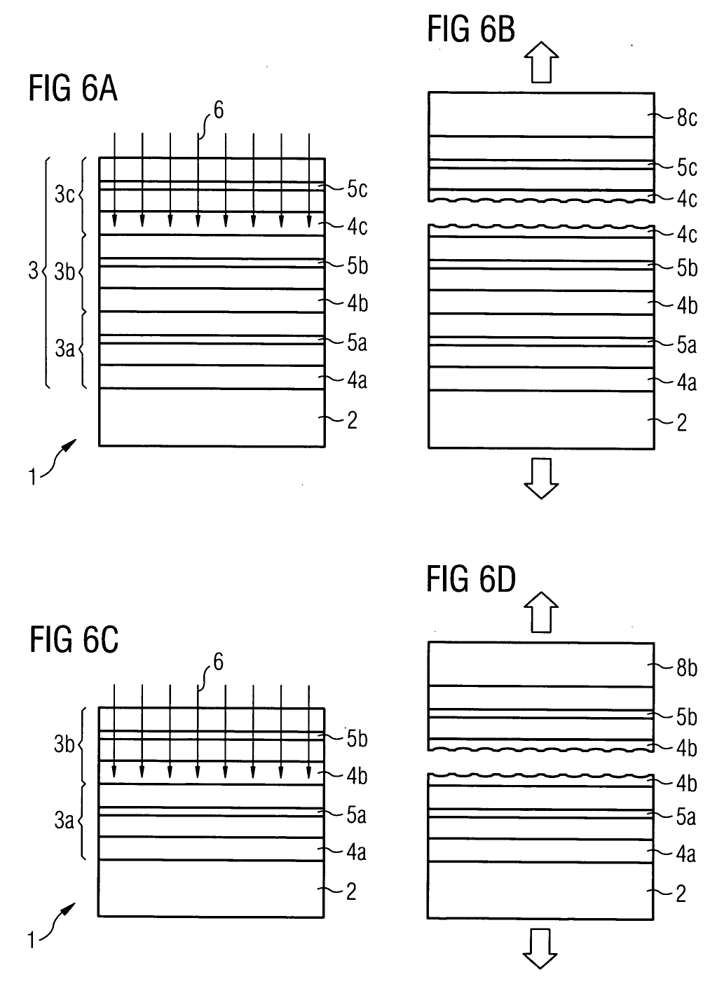

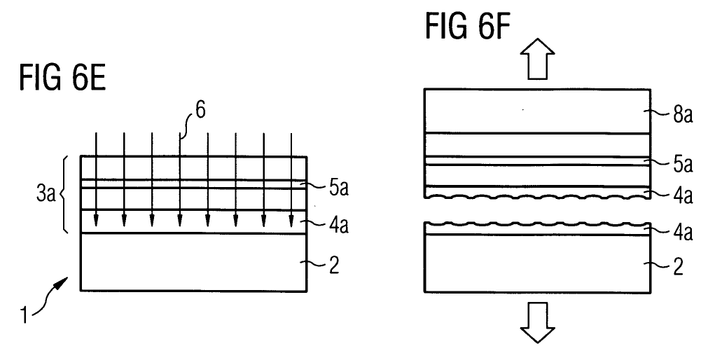

FIGS. 6A to 6F show schematic illustrations of cross sections through a semiconductor wafer during intermediate steps of a method in accordance with a sixth exemplary embodiment of the invention.

Identical or identically acting elements are provided with the same reference symbols in the figures. The elements illustrated should not be regarded as true to scale, rather individual elements may be illustrated with an exaggerated size in order to afford a better understanding.

FIG. 1A illustrates schematically in cross section a semiconductor wafer 1 comprising a growth substrate 2 and a semiconductor layer sequence 3 applied epitaxially to the growth substrate 2. The semiconductor layer sequence 3 is applied to the growth substrate 2 for example by means of metal organic vapor phase epitaxy (MOVPE). The epitaxial semiconductor layer sequence 3 is preferably based on a nitride compound semiconductor.

The growth substrate 2 is preferably a substrate suitable for epitaxially growing a nitride compound semiconductor, which substrate can be in particular a GaN substrate, an AlN substrate, an SiC substrate or a sapphire substrate.

The epitaxial semiconductor layer sequence 3 contains at least one functional semiconductor layer 5, for example a radiation-emitting or radiation-detecting layer provided for an optoelectronic component.

In particular, the functional semiconductor layer 5 can be an active layer of a luminescence diode or of a semiconductor laser. In this case, the active layer can be formed for example as a heterostructure, double heterostructure or as a quantum well structure. In this case, the designation quantum well structure encompasses any structure in which charge carriers experience a quantization of their energy states by means of confinement. In particular, the designation quantum well structure does not comprise any indication about the dimensionality of the quantization. It therefore encompasses, inter alia, quantum wells, quantum wires and quantum dots and any combination of these structures.

Furthermore, the epitaxial semiconductor layer sequence 3 contains a separating layer 4 arranged between the growth substrate 2 and the functional semiconductor layer 5.

Ions are implanted into the separating layer 4 through the functional semiconductor layer 5, as is indicated by the arrows 6. The implanted ions can be in particular hydrogen ions, or alternatively ions of noble gases such as, for example, helium, neon, krypton or xenon. It is also possible for ions of different atoms to be implanted, in particular hydrogen ions and helium ions or hydrogen ions and boron ions. This has the advantage that the required implantation dose is reduced.

Afterward, as illustrated in FIG. 1B, the semiconductor wafer 1 is connected to a carrier substrate 8 at a surface opposite to the growth substrate 2. The carrier substrate 8 is preferably connected to the semiconductor wafer 1 by means of soldering or bonding. By way of example, the carrier substrate 8 can be connected to a layer of the semiconductor layer sequence 3. As an alternative, the semiconductor layer sequence 3 can be provided with a contact layer and/or reflection-increasing layer 9 prior to connecting to the carrier substrate 8.

Since, in contrast to the growth substrate 2, the carrier substrate 8 does not have to be suitable for epitaxially growing the semiconductor layer sequence 3, which is based for example on a nitride compound semiconductor material, there is comparatively high freedom in the material selection for the carrier substrate 8. In particular, a carrier substrate 8 can be selected which is distinguished by comparatively low costs and/or a good thermal conductivity. By way of example, the carrier substrate 8 can be formed from Ge, GaAs, a metal such as, for example Mo or Au, a metal alloy, or a ceramic such as, for example, AlN.

Afterward, as indicated by the arrow T in FIG. 1B, a thermal treatment is carried out, which brings about diffusion of the ions implanted into the separating layer 4. The thermal treatment is preferably effected at a temperature of between 300° C. and 1200° C. The diffusion of the implanted ions in the separating layer 4 which is excited by the thermal treatment leads to a formation of blisters 7 in the separating layer 4, the size and number of which increase as the duration of the thermal treatment increases.

The formation of blisters 7 which is brought about by the diffusion of the implanted ions finally leads, as is illustrated schematically in FIG. 1C, to the semiconductor wafer 1 being divided into a first part 1a, which contains the growth substrate 2, and a second part 1b, which contains the functional semiconductor layer 5.

The part 1b of the semiconductor wafer 1 which is separated from the growth substrate 2 can be in particular an optoelectronic component, for example a luminescence diode or a semiconductor laser, or be processed further to form an optoelectronic component. Furthermore, the separated part 1b of the semiconductor wafer can also be singulated to form a plurality of optoelectronic components.

After the semiconductor wafer 1 has been divided into two parts 1a, 1b, the residues of the separating layer 4 which remain on the growth substrate 2 and/or on the separated part of the semiconductor layer sequence 3 can be smoothed or else completely removed by means of an etching or polishing process.

The growth substrate 2, which is for example a high-priced substrate composed of GaN, AlN, SiC or sapphire, can therefore be completely reused for growing further semiconductor layer sequences. In this way it is possible in particular to produce epitaxial semiconductor layer sequences for a multiplicity of optoelectronic components on a single growth substrate. The production costs are advantageously reduced thereby.

In order to simplify the dividing of the semiconductor wafer 1 into two parts 1a, 1b as illustrated schematically in FIG. 1C, it is advantageous if the depth profile of the ions implanted into the separating layer 4 has a comparatively small full width at half maximum. For this purpose, the material of the separating layer 4 is advantageously chosen in such a way that it represents a stop layer for the implanted ions. For this purpose, the separating layer 4 advantageously contains at least one element which has a higher atomic number than gallium. By way of example, the separating layer 4 can be a nitride compound semiconductor layer containing indium. At the atoms of the element having a high atomic number which are contained in the separating layer 4, the ions are decelerated to a comparatively great extent during the ion implantation, whereby an advantageously narrow concentration profile is produced within the separating layer 4. With such a separating layer 4 functioning as a stop layer for the implanted ions, the ions can advantageously be implanted into the separating layer 4 through the functional semiconductor layer 5 with a comparatively high ion energy, in which case a widening of the concentration profile that otherwise occurs is reduced, on account of the high ion energy, by the separating layer 4 acting as a stop layer. The use of a high ion energy during the ion implantation is advantageous because the semiconductor layer sequence 3 to be separated from the semiconductor wafer 1 is damaged to a lesser extent in this case. Deep penetration of the implanted ions into the semiconductor layer sequence can be obtained in particular by utilizing lattice guiding (channeling).

Dividing the semiconductor wafer 1 can be simplified by forming the separating layer 4 as a desired breaking location. This should be understood to mean that the separating layer 4 is to be divided or separated from the adjacent layers with comparatively low outlay for example on account of its structure or on account of mechanical stresses. In particular, the separating layer 4 can be a tensile-stressed layer. This means that the separating layer 4 has a smaller lattice constant than at least one adjacent semiconductor layer or the growth substrate 2.

In particular, the tensile-stressed separating layer can be a nitride compound semiconductor layer containing aluminum. In this case, the proportion of aluminum in the tensile-stressed layer is advantageously greater than that in at least one semiconductor layer adjoining the separating layer 4 and/or in the growth substrate 2. Furthermore, a tensile stress of a separating layer 4 based on a nitride compound semiconductor can also be obtained by a doping of the separating layer 4 with atoms having a lower atomic number than gallium, for example by a doping with silicon.

In the intermediate step illustrated schematically in FIG. 2 in an exemplary embodiment of the method according to the invention, the separating layer 4 is a layer produced by epitaxial lateral overgrowth (ELOG). In order to produce the ELOG layer, a mask layer 10 is applied to the growth substrate 2 in patterned fashion, or, if the separating layer 4 is not applied directly to the growth substrate 2, is applied to a semiconductor layer arranged below the separating layer 4 in the growth direction. The mask layer 10 can be in particular a silicon nitride or silicon oxide layer.

The separating layer 4 produced as an ELOG layer simplifies dividing the semiconductor wafer 1 since the semiconductor material of the separating layer 4 has comparatively low adhesion on the regions of the mask layer 10 which are laterally overgrown. The semiconductor wafer 1 can therefore be divided with comparatively low outlay in a plane running along a surface of the mask layer 10 which faces the separating layer 4.

Instead of an ELOG mask layer 10, it is also possible to use an in-situ SiN layer for growing the separating layer by means of lateral overgrowth. An in-situ SiN layer is applied as such a thin layer that it has not yet grown together to form a continuous layer and therefore does not completely cover the growth substrate. In this way, the in-situ SiN layer functions as a mask layer.

In a further preferred exemplary embodiment, as illustrated schematically in FIG. 3, a diffusion barrier layer 11 is arranged above the separating layer 4 in the growth direction of the semiconductor layer sequence 3. The diffusion barrier layer 11 is preferably an undoped or n-doped nitride compound semiconductor layer, for example a Zn-doped GaN layer or an Si-doped n-GaN layer. In particular, the diffusion barrier layer 11 is not p-doped.

The diffusion barrier layer 11 advantageously reduces diffusion of the ions implanted into the separating layer 4 into overlying semiconductor layers, in particular into the functional semiconductor layer 5. The schematically illustrated depth profile of the concentration D of the implanted ions is narrowed toward the top in this way. Damage to the functional semiconductor layer by diffusing ions is prevented in this way.

In the exemplary embodiment illustrated in FIG. 4, in contrast to the exemplary embodiment illustrated in FIG. 3, a diffusion barrier layer 12 is arranged below rather than above the separating layer 4. By virtue of the diffusion barrier layer 12 arranged below the separating layer 4 in the growth direction, advantageously diffusion of the implanted ions into the growth substrate 2 is reduced and the schematically illustrated depth profile of the concentration D of the implanted ions is narrowed toward the growth substrate 2.

Particularly preferably, as illustrated in FIG. 5, diffusion barrier layers 11, 12 are arranged both below and above the separating layer 4. In this case, the depth profile of the concentration D of the implanted ions is advantageously narrowed on both sides of the separating layer 4 by a reduction of the diffusion of the ions into the adjoining layers and the growth substrate. It goes without saying that the use of diffusion barrier layers above and/or below the separating layer 4 as explained with reference to FIGS. 3 to 5 can be combined with the advantageous configurations of the separating layer 4 described in connection with FIGS. 1 and 2.

A further advantageous configuration of the method according to the invention is explained below on the basis of the intermediate steps illustrated schematically in FIGS. 6A to 6F.

The semiconductor wafer 1 illustrated in FIG. 6A contains a semiconductor layer sequence 3 composed of three partial layer sequences 3a, 3b, 3c arranged one above another, said semiconductor layer sequence being grown epitaxially on a growth substrate 2. Instead of three partial layer sequences, the semiconductor layer sequence 3 can also have any other number of partial layer sequences arranged one above another. Each of the partial layer sequences 3a, 3b, 3c contains a separating layer 4a, 4b, 4c and in each case at least one functional semiconductor layer 5a, 5b, 5c succeeding the separating layer in the growth direction.

As illustrated schematically in FIGS. 6A, 6B, 6C, 6D, 6E and 6F, the partial layer sequences 3a, 3b and 3c are successively separated from the semiconductor wafer 1 by repeating the method step of ion implantation and subsequently dividing the semiconductor wafer along the respective separating layers 4a, 4b, 4c.

The ion implantation is effected here in each case into the topmost one of the separating layers still present on the semiconductor wafer 1. By way of example, FIG. 6A illustrates the ion implantation into the initially topmost separating layer 4c contained in the partial layer sequence 3c. FIG. 6B illustrates the dividing of the semiconductor wafer along the topmost separating layer 4c. Prior to the separating method step, the semiconductor layer sequence 3 was connected to a carrier substrate 8c at the surface remote from the growth substrate 2. The residues of the severed separating layer 4c which remain after the separating method step on the partial layer sequence 3b and/or on that side of the separated partial layer sequence 3c which is remote from the carrier substrate 8c are advantageously smoothed or removed by an etching or polishing process.

Afterward, the method steps of ion implantation and separating are repeated in accordance with the number of partial layer sequences. By way of example, FIG. 6C illustrates the method step of ion implantation into the separating layer 4b, which is the topmost separating layer after the separation of the upper partial layer sequence 3c illustrated in FIG. 6B.

FIG. 6D shows the dividing of the semiconductor wafer along the separating layer 4b, the partial layer sequence 3b being transferred to a carrier substrate 8b.

By means of a further repetition—illustrated in FIGS. 6E and 6F—of the ion implantation and the dividing of the semiconductor wafer along the separating layer 4a, the partial layer sequence 3a is also transferred to a carrier substrate 8a. After progressively separating the plurality of partial layer sequences 3a, 3b, 3c, residues of the separating layer 4a that are possibly present are removed from the growth substrate 2. The growth substrate 2 can therefore advantageously be used again for growing a semiconductor layer sequence 3 composed of a plurality of partial layer sequences 3a, 3b, 3c.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or exemplary embodiments.

1. A method for laterally dividing a semiconductor wafer containing a growth substrate and a semiconductor layer sequence, comprising the steps of:
providing the growth substrates;
epitaxially growing the semiconductor layer sequence onto the growth substrate, the semiconductor layer sequence comprising a layer provided as a separating layer and at least one functional semiconductor layer which succeeds the separating layer in the growth direction;
implanting ions through the functional semiconductor layer into the separating layer; and
dividing the semiconductor wafer, a part of the semiconductor wafer which contains the growth substrate being separated along the separating layer.

2. The method as claimed in claim 1,
wherein
dividing is effected by means of a thermal treatment.

3. The method as claimed in claim 1,
wherein
the thermal treatment is effected at a temperature within the range of 300° C. to 1200° C.

4. The method as claimed in claim 1,
wherein
the growth substrate is a GaN substrate or an AlN substrate.

5. The method as claimed in claim 1,
wherein
the semiconductor layer sequence is based on a nitride compound semiconductor material.

6. The method as claimed in claim 1,
wherein
hydrogen ions, helium ions, hydrogen ions and helium ions, or hydrogen ions and boron ions are implanted during the ion implantation.

7. The method as claimed in claim 1,
wherein
thermal annealing of the semiconductor layer sequence is effected after the ion implantation.

8. The method as claimed in claim 1,
wherein
the separating layer contains at least one element which has a higher atomic number than gallium.

9. The method as claimed in claim 8,
wherein
the separating layer contains indium.

10. The method as claimed in claim 1,
wherein
the semiconductor layer sequence contains at least one diffusion barrier layer—adjacent to the separating layer—for the implanted ions.

11. The method as claimed in claim 10,
wherein
the diffusion barrier layer is a nitride compound semiconductor layer doped with Zn, Fe or Si.

12. The method as claimed in claim 10,
wherein
the semiconductor layer sequence contains diffusion barrier layers for the implanted ions on both sides of the separating layer.

13. The method as claimed in claim 12,
wherein
the separating layer is a tensile-stressed layer.

14. The method as claimed in claim 13,
wherein
the tensile-stressed separating layer is a nitride compound semiconductor layer containing aluminum.

15. The method as claimed in claim 13,
wherein
the tensile-stressed separating layer is a Si-doped nitride compound semiconductor layer.

16. The method as claimed in claim 1,
wherein
the separating layer is a semiconductor layer produced by lateral epitaxial overgrowth (ELOG).

17. The method as claimed in claim 1,
wherein
the separating layer is formed from a semiconductor material in which the implanted ions have a greater diffusion coefficient than in a layer adjoining the separating layer.

18. The method as claimed in claim 17,
wherein
the separating layer is a p-doped nitride compound semiconductor layer.

19. The method as claimed in claim 1,
wherein
the semiconductor wafer is connected to a carrier substrate prior to dividing at a surface remote from the growth substrate.

20. The method as claimed in claim 1,
wherein
the functional semiconductor layer is a radiation-emitting layer or a radiation-detecting layer.

21. The method as claimed in claim 1,
wherein
the functional semiconductor layer comprises InₓAl_{y}Ga_{1-x-y}N where 0≦x≦1, 0≦y≦1 and x+y≦1.

22. The method as claimed in claim 1,
wherein
the semiconductor layer sequence contains a number of further separating layers which succeed the separating layer in the growth direction, wherein the method further comprises, prior to the step of ion implantation into the separating layer, the steps of:
a) ion implantation into an upper separating layer, the upper separating layer being that one of the further separating layers which is at the greatest distance from the growth substrates;
b) dividing the semiconductor wafer along the upper separating layer; and
c) repeatedly carrying out method steps a) and b), the number of repetitions being equal to the number of further separating layers.

23. An optoelectronic component comprising a semiconductor layer sequence having a functional semiconductor layer,
in which the semiconductor layer sequence was separated from a growth substrate by a method as claimed in claim 1.
